(19) United States
(12) Patent Application Publication
(10) Pub. No.: US 2014/0346465 A1
(43) Pub. Date: Nov. 27, 2014

(54) ORGANIC LIGHT-EMITTING DISPLAY APPARATUS AND METHOD OF MANUFACTURING THE SAME

(71) Applicant: SAMSUNG DISPLAY CO., LTD., Yongin-City (KR)

(72) Inventor: YOUNG-IL KIM, Yongin-City (KR)

(73) Assignee: SAMSUNG DISPLAY CO., LTD., Yongin-City (KR)

(21) Appl. No.: 14/083,828

(22) Filed: Nov. 19, 2013

(30) Foreign Application Priority Data
May 23, 2013 (KR) 10-2013-0058537

(51) Int. Cl. H01L 27/32; H01L 51/00

(52) U.S. Cl. CPC H01L 27/326; H01L 51/0004
USPC 257/40; 438/23

(57) ABSTRACT

An organic light-emitting display apparatus including a thin film transistor including a gate electrode, an active layer insulated from the gate electrode, a source electrode and a drain electrode insulated from the gate electrode and contacting the active layer, and an insulating layer disposed between the source and drain electrodes and the active layer. The organic light-emitting display apparatus further includes an organic light-emitting diode including a first electrode, a second electrode and an organic layer disposed between the first electrode and the second electrode. The organic light-emitting diode is electrically connected to the thin film transistor. The drain electrode overlaps with a ortion of the organic light-emitting diode.

### CROSS-REFERENCE TO RELATED PATENT APPLICATION

This application claims priority to Korean Patent Application No. 10-2013-0058537, filed on May 23, 2013, the disclosure of which is hereby incorporated by reference herein in its entirety.

### TECHNICAL FIELD

The present disclosure relates to an organic light-emitting display apparatus and method of manufacturing the same, and more particularly, to an organic light-emitting display apparatus having increased optical properties and a method of manufacturing the same.

### DISCUSSION OF THE RELATED ART

An organic light-emitting display apparatus is a self-emissive display apparatus that may include, for example, a hole injecting electrode, an electron injecting electrode, and an organic light-emitting layer formed between the hole injecting electrode and electron injecting electrode. In the organic light-emitting display apparatus, light is generated as holes injected from an anode and electrons injected from a cathode recombine in the organic light-emitting layer to an excited state that gradually decays thereafter.

The organic light-emitting display apparatus has high-quality features such as, for example, low power consumption, high-luminance, and fast response. Thus, the organic light-emitting display apparatus has drawn attention as a next-generation display apparatus. However, if the thickness of the organic light-emitting layer is non-uniform, the optical properties of regions near pixel defining layers may be degraded.

### SUMMARY OF THE INVENTION

Exemplary embodiments of the present invention provide an organic light-emitting display apparatus having increased optical properties and a method of manufacturing the same.

According to an exemplary embodiment of the present invention, there is provided an organic light-emitting display apparatus including a thin film transistor including a gate electrode, an active layer insulated from the gate electrode, a source electrode and a drain electrode insulated from the gate electrode and contacting the active layer, and an insulating layer disposed between the source and drain electrodes and the active layer, and an organic light-emitting diode including a first electrode, a second electrode and an organic layer disposed between the first electrode and the second electrode. The organic light emitting diode is electrically connected to the thin film transistor. In addition, the drain electrode is formed to overlap with a portion of the organic light-emitting diode.

The organic light-emitting diode may be a bottom emission type organic light-emitting diode that is configured to emit light through a substrate.

The organic light-emitting display apparatus according to an exemplary embodiment of the present invention may further include an auxiliary pattern that is spaced apart from the drain electrode and overlaps with a portion of the organic light-emitting diode.

The auxiliary pattern and the drain electrode, which overlaps the organic light-emitting diode, may be formed on a same plane as each other.

An overlapping distance of the drain electrode and the organic light-emitting diode may be substantially equal to an overlapping distance of the auxiliary pattern and the organic light-emitting diode.

The organic layer may be formed by using a printing method.

The printing method may be an inkjet printing method, a nozzle printing method, a gravure printing method, a screen printing method, a spray printing method, or an electrostatic printing method.

The organic light-emitting display apparatus according to an exemplary embodiment of the present invention may further include an auxiliary electrode including a first conductive pattern disposed on the insulating layer, and a second conductive pattern disposed on the first conductive pattern and contacting the second electrode.

The first conductive pattern and the drain electrode, which overlaps the organic light-emitting diode, may be formed on a same plane as each other.

The organic light-emitting display apparatus according to an aspect of the present invention may further include an encapsulating layer encapsulating the organic light-emitting diode.

According to an exemplary embodiment of the present invention, there is provided a method of manufacturing an organic light-emitting display apparatus, the method including forming a gate electrode on a substrate, forming a gate insulating layer covering the gate electrode, forming an active layer on the gate insulating layer, forming an insulating layer covering at least a channel region of the active layer, forming a source electrode and a drain electrode contacting the active layer on the insulating layer and forming an organic light-emitting diode electrically connected to either one of the source and drain electrodes, and including a first electrode, a second electrode and an organic layer disposed between the first electrode and the second electrode. The forming of the drain electrode includes overlapping the drain electrode with a portion of the organic light-emitting diode.

The forming of the organic light-emitting diode, the organic light-emitting diode may be formed as a bottom emission type light-emitting diode that is configured to emit light through the substrate.

The forming of the source and drain electrodes may further include forming an auxiliary pattern that is spaced apart from the drain electrode and overlaps with a portion of the organic light-emitting diode.

In the forming of the auxiliary pattern, the auxiliary pattern and the drain electrode may be formed on a same plane as each other.

In the forming of the auxiliary pattern, the auxiliary pattern may be formed of the same material as the source and drain electrodes.

In the forming of the organic light-emitting diode, the organic layer may be formed by using a printing method.

The printing method may be an inkjet printing method, a nozzle printing method, a gravure printing method, a screen printing method, a spray printing method, or an electrostatic printing method.

The forming of the source and drain electrodes may further include forming a first conductive pattern on the insulating layer, and forming a second conductive pattern on the first conductive pattern to contact the second electrode.

The method of manufacturing an organic light-emitting apparatus according to another aspect of the present invention may further include, before the forming of the gate electrode, forming a barrier layer on the substrate.

The method of manufacturing an organic light-emitting apparatus according to another aspect of the present invention may further include, after the forming of the organic light-emitting diode, forming an encapsulating layer encapsulating the organic light-emitting diode.

In accordance with an exemplary embodiment, an organic light-emitting display apparatus is provided. The organic light-emitting display apparatus includes a thin film transistor including a substrate, an active layer disposed on the substrate, a gate insulating layer disposed on the active layer, a gate electrode disposed on the gate insulating layer, an insulating layer disposed on the gate electrode and the gate insulating layer, and a source electrode and a drain electrode disposed on the insulating layer and penetrating the insulating layer and the gate insulating layer. The source electrode and the drain electrode are electrically connected to the active layer.

In addition, the organic light-emitting display apparatus further includes an organic light-emitting diode including a first electrode disposed on the thin film transistor, a second electrode disposed on the first electrode and an organic layer disposed between the first electrode and the second electrode. The organic light emitting diode is electrically connected to the thin film transistor. In addition, the drain electrode overlaps with a first portion of a lower region of the organic light-emitting diode.

### BRIEF DESCRIPTION OF THE DRAWINGS

Exemplary embodiments of the present invention can be understood in more detail from the following detailed description taken in conjunction with the attached drawings in which:

FIG. 1 is a cross-sectional view illustrating an organic light-emitting display apparatus according to an embodiment of the present invention;

FIG. 2 is a cross-sectional view illustrating an organic light-emitting display apparatus according to an embodiment of the present invention; and

FIGS. 3 through 10 are cross-sectional views illustrating a method of manufacturing an organic light-emitting display apparatus according to an embodiment of the present invention.

### DETAILED DESCRIPTION OF EXEMPLARY EMBODIMENTS OF THE INVENTION

Hereinafter, exemplary embodiments of the present invention will be described more fully with reference to the accompanying drawings, in which exemplary embodiments of the invention are shown.

The terminology used herein is for the purpose of describing exemplary embodiments only and is not intended to limit exemplary embodiments of the invention. As used herein, the singular forms ‘a’, ‘an’ and ‘the’ are intended to include the plural forms as well, unless the context clearly indicates otherwise. It will be further understood that the terms ‘comprise’ and ‘include’ when used in this specification, specify the presence of stated features, integers, steps, operations, elements, and/or components, but do not preclude the presence or addition of one or more other features, integers, steps, operations, elements, components, and/or groups thereof.

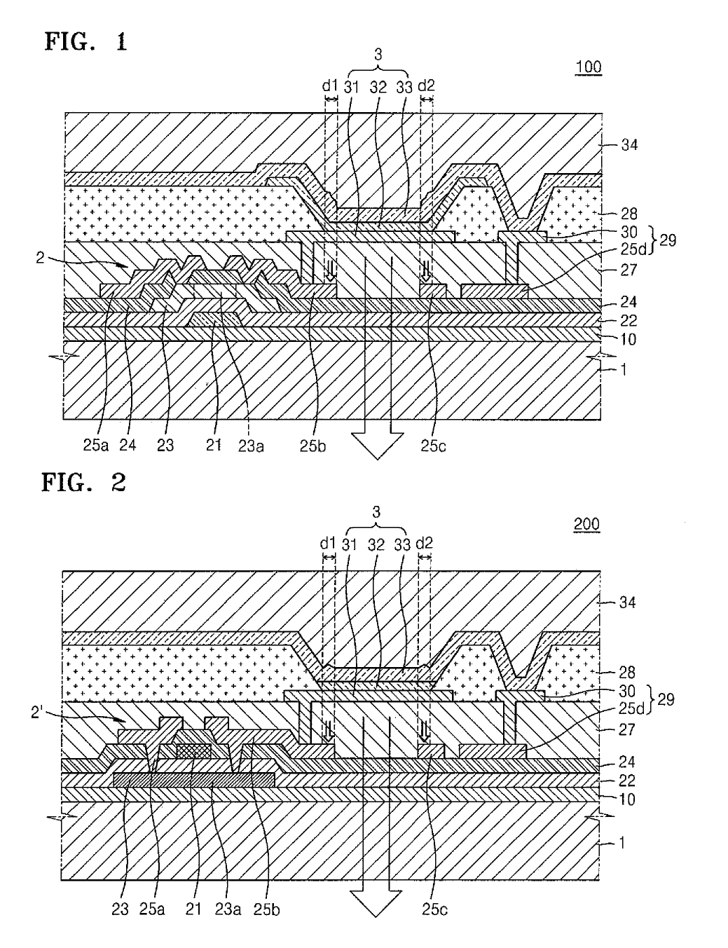

FIG. 1 is a cross-sectional view illustrating an organic light-emitting display apparatus 100 according to an embodiment of the present invention.

The organic light-emitting display apparatus 100 according to the present embodiment includes, for example, a substrate 1, a thin film transistor 2 formed on the substrate 1, an organic light-emitting diode 3, and a drain electrode 25b and an auxiliary pattern 25c formed to overlap a predetermined portion of an outer region of the organic light-emitting diode 3. Therefore, the organic light-emitting diode 3 may emit only light of uniform luminance, and thus, the optical properties of the organic light-emitting display apparatus 100 may be increased.

The organic light-emitting display apparatus 100 according to the present embodiment includes, for example, a plurality of pixels, and a portion of one of the pixels of the organic light-emitting display apparatus 100 is illustrated in FIG. 1.

The substrate 1 may be formed of, for example, transparent glass, quartz, plastic, or the like. Also, in an exemplary embodiment, the substrate 1, may be formed of, for example, ceramic or silicon materials. For example, substrate 1 may be formed of a plastic material such as polyethyelneterepthalate (PET), polyethylenennapthalate (PEN), polycarbonate (PC), polyallylate, polyetherimide (PEI), polyethersulphone (PES), or polyimide. Also, the substrate 1 may be, for example, a metal substrate formed of thin glass or stainless steel. In addition, the substrate 1 may be a flexible substrate formed of, for example, various flexible materials.

The thin film transistor 2 includes, for example, a gate electrode 21, a gate insulating layer 22 covering the gate electrode 21, an active layer 23 formed on the gate insulating layer 22, an insulating layer 24 formed on the gate insulating layer 22 to cover the active layer 23, and a source electrode 25a and the drain electrode 25b formed on the insulating layer 24 and contacting the active layer 23. The thin film transistor 2 drives the organic light-emitting diode 3.

The gate electrode 21 is formed of, for example, a conductive metal, and may be a single layer or a multi-layer formed from at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), zinc (Zn), cobalt (Co), manganese (Mn), iridium (Ir), rhodium (Rh), osmium (Os), tantalum (Ta), or an alloy thereof. For example, in an embodiment, the gate electrode 21 may include molybdenum.

The gate insulating layer 22 may be formed of, for example, silicon oxide (SiOx), silicon oxynitride (SiOxNy), tantalum oxide, aluminum oxide (AlOx), yttrium oxide (Y₂O₃), hafnium oxide (HfOx), zirconium oxide (ZrOx), aluminum nitride (AlN), aluminum oxynitride (AlNO), titanium oxide (TiOx), barium titanate (BaTiO3), lead titanate (PbTiO₃), or a combination thereof, but exemplary embodiments of the present invention are not limited thereto.

The active layer 23 is patterned on the gate insulating layer 22. The active layer 23 may be formed of, for example, oxide semiconductors, and may include at least one selected from the group consisting of gallium (Ga), indium (In), zinc (Zn), tin (Sn), and hafnium (Hf), and oxygen. For example, the active layer 23 may include materials such as zinc oxide (ZnO), zinc gallium oxide (ZnGaO), zinc indium oxide (ZnInO), gallium indium oxide (GalnO), gallium tin oxide (GaSnO), zinc tin oxide (ZnSnO), indium tin oxide (InSnO), hafnium indium zinc oxide (HfInZnO), or zinc gallium indium oxide (ZnGafnO), and may be a gallium-indium-zinc-oxide (GIZO) layer including a(In2O3), b(Ga2O3), and c(ZnO) (a, b, and c are real numbers such that a≧0, b≧0, and c≧0).

The insulating layer 24 is formed to cover the active layer 23. The insulating layer 24 protects a channel 23a of the active layer 23. As illustrated in FIG. 1, the insulating layer 24 may be formed, for example, to cover the active layer 23 except for a region of the active layer 23 that contacts the source and drain electrodes 25a and 25b. However, the insulating layer 24 according to the present embodiment is not limited thereto. Although not illustrated in FIG. 1, the insulating layer 24 may be formed, for example, only on an upper portion of the channel 23a.

The source and drain electrodes 25a and 25b are formed on the insulating layer 24 to contact the active layer 23. The source and drain electrodes 25a and 25b may be formed of at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), zinc (Zn), cobalt (Co), manganese (Mn), iridium (Ir), rhodium (Rh), osmium (Os), tantalum (Ta), or an alloy thereof.

The drain electrode 25b is formed, for example, to overlap a predetermined portion of an outer region of the organic light-emitting diode 3.

If the organic light-emitting display apparatus 100 is a bottom-emissive type, the drain electrode 25b is not formed to overlap the bottom of the organic light-emitting diode 3. Therefore, if a thickness of an organic layer 32 of the light-emitting diode 3 is non-uniform, the luminance of the organic layer 32 may vary around a pixel defining layer 28, and thus, the optical properties of the organic light-emitting diode 3 may be degraded.

However, according to the present embodiment, to address the difficulty of when the thickness of the organic layer 32 of the organic light-emitting diode 3 is non-uniform, the drain electrode 25b is formed to overlap a predetermined portion of a lower region of the organic light-emitting diode 3. An overlapped distance dl of the drain electrode 25b and the organic light-emitting diode 3 may be determined based on the thickness uniformity of the organic layer 32 of the organic light-emitting diode 3. For example, if the thickness of the organic layer 32 is non-uniform only in a narrow region near the pixel defining layer 28, the drain electrode 25b may be formed to overlap the narrow region. On the other hand, if the thickness of the organic layer 32 is non-uniform in a wide region around the pixel defining layer 28, the drain electrode 25b may be formed, for example, to overlap the wide region and the organic layer 32. Thus, the drain electrode 25b may prevent light of a different luminance from being emitted from the narrow or wide regions.

In addition, when forming the source and drain electrodes 25a, 25b, the auxiliary pattern 25c is formed on the insulating layer 24. The auxiliary pattern 25c may be formed of, for example, the same material as the source and drain electrodes 25a and 25b.

The auxiliary pattern 25c is, for example, spaced apart from the drain electrode 25b, and formed on the insulating layer 24. To overlap a predetermined portion of the outer region of the organic light-emitting diode 3, the auxiliary pattern 25c is formed, for example, in the lower region of the organic light-emitting diode 3.

According to the present embodiment, to address the difficulty of when the thickness of the organic layer 32 formed in the organic light-emitting diode 3 is non-uniform, the auxiliary pattern 25c is formed to overlap a predetermined portion of the lower region of the organic light-emitting diode 3. An overlapped distance d2 of the auxiliary pattern 25c and the organic light-emitting diode 3 may be determined according to the thickness uniformity of the organic layer 32 of the organic light-emitting diode 3. For example, if the thickness of the organic layer 32 is non-uniform only in a narrow region near the pixel defining layer 28, the auxiliary pattern 25c may be formed to overlap the narrow region. On the other hand, if the thickness of the organic layer 32 is non-uniform in a wide region around the pixel defining layer 28, the auxiliary pattern 25c may be formed to, for example, overlap the wide region and the organic layer 32.

Additionally, when forming the source and drain electrodes 25a and 25b, a first conductive pattern 25d may be formed on the insulating layer 24. The first conductive pattern 25d may be formed of, for example, the same material as the source and drain electrodes 25a and 25b.

A second conductive pattern 30 is formed on the first conductive pattern 25d to form an auxiliary electrode 29 which may supply auxiliary power to a second electrode 33. The auxiliary electrode 29 supplies power to the second electrode 33, and thus, prevents the occurrence of an IR drop. Thus, the luminance and display quality of the organic light-emitting display apparatus 100 may be increased.

A passivation layer 27 is formed on the insulating layer 24 to cover the source and drain electrodes 25a and 25b, the auxiliary pattern 25c, and the first conductive pattern 25d. The passivation layer 27 may include, for example, an inorganic insulator such as silicon nitride (SiNx) and silicon oxide (SiOx) or an organic insulator. For example, the organic insulator of the passivation layer 27 may include benzocyclobutene (BCB), acryl-based resin or a combination thereof.

A first electrode 31 of the organic light-emitting diode 3, which contacts the drain electrode 25b, and the second conductive pattern 30, which contacts the first conductive pattern 25d, are formed on the passivation layer 27.

The pixel defining layer 28, which exposes portions of the first electrode 31 and the second conductive pattern 30, is formed on the passivation layer 27. The pixel defining layer 28 may include, for example at least one selected from the group consisting of benzocyclicbutene (BCB), acryl-based polymer and polyimide. The organic layer 32 and the second electrode 33 of the organic light-emitting diode 3 are formed on an upper portion of the first electrode 31 that is exposed to the pixel defining layer 28. The second electrode 33 contacts an upper portion of the auxiliary electrode 29, that is, an exposed area of the second conductive pattern 30.

For example, the pixel defining layer 28 is formed to cover edges of the first electrode 31 and the auxiliary electrode 29. The pixel defining layer 28 not only defines light-emitting regions, but also widens a gap between the edge of the first electrode 31 and the second electrode 33, and thus, prevents the concentration of an electric field at the edge of the first electrode 31. Therefore, a short circuit between the first and second electrodes 31 and 33 may be prevented.

The first electrode 31 is patterned on each pixel. The first electrode 31 is a transparent electrode, and may be formed of, for example, indium tin oxide (ITO), indium zinc oxide (IZO), zinc oxide (ZnO), or indium oxide (In₂O₃).

The second electrode 33 is a reflective electrode, and may be formed by forming, for example, a reflective layer using silver (Ag), magnesium (Mg), aluminum (Al), platinum (Pt), palladium (Pd), gold (Au), nickel (Ni), neodymium (Nd), iridium (Ir), chromium (Cr) or a compound thereof and forming a layer using ITO, IZO, ZnO, or In₂O₃ on the reflective layer.

If the first electrode 31 functions as an anode, the second electrode 33 functions as a cathode and vice versa.

The organic layer 32 interposed between the first and second electrodes 31 and 33 may include, for example, all of or selectively include a hole injection layer (HIL), an emission layer (EML), and an electron injection layer (EIL). However, the organic layer should at least include the EML

The organic layer 32 may be formed by using, for example, a printing method. For example, by using an inkjet printing method, a nozzle printing method, a gravure printing method, a screen printing method, a spray printing method, or an electrostatic printing method, an organic material is injected into the exposed upper portion of the first electrode 31, and is dried to form the organic layer 32.

If the thickness of the organic layer 32 formed on the first electrode 31 is non-uniform, the optical properties of the organic light-emitting diode 3 near the pixel defining layer 28 may be degraded. However, as described above, degradation of the optical properties may be limited by using the drain electrode 25b and the auxiliary pattern 25c. Thus, a detailed description in this regard will be omitted.

Also, the organic light-emitting display apparatus 100 may further include, for example, a barrier layer 10 interposed between the substrate 1 and the thin film transistor 2.

The barrier layer 10 may be formed of, for example, at least one of various inorganic and organic layers. Moisture passing through the organic light-emitting display apparatus 100 decreases the lifetime of the organic light-emitting diode 3. Thus, the barrier layer 10 prevents unnecessary impurities such as, for example, moisture from passing through the substrate 1 and penetrating into the organic light-emitting diode 3.

An encapsulating layer 34 is formed to encapsulate the second electrode 33. Although not illustrated in detail, the encapsulating layer 34 may be formed to have, for example, a multi-layered structure. The encapsulating layer 34 may be formed, for example, of a plurality of inorganic layers, or alternately stacked inorganic and organic layers. According to an embodiment of the present invention, the encapsulating layer 34 may be formed by using, for example, various types of inorganic and organic layers well-known to one of ordinary skill in the art.

FIG. 2 is a cross-sectional view illustrating an organic light-emitting display apparatus 200 according to an embodiment of the present invention. Like reference numerals in FIGS. 1 and 2 denote like elements and descriptions thereof will be omitted.

Referring to FIG. 2, the organic light-emitting display apparatus 200 includes, for example, a substrate 1, a thin film transistor 2′ formed on the substrate 1, an auxiliary pattern 25c, and an organic light-emitting diode 3. The organic light-emitting display apparatus 200 according to the present embodiment includes, for example, a plurality of pixels, and a portion of one of the pixels of the organic light-emitting display apparatus 200 is illustrated in FIG. 2.

Unlike the thin film transistor 2 of FIG. 1, the thin film transistor 2′ includes, for example, the substrate 1, an active layer 23 formed on the substrate 1, a gate insulating layer 22 formed on the active layer 23, a gate electrode 21 insulated from the active layer 23 and a source electrode 25a and a drain electrode 25b, which penetrate an insulating layer 24 and the gate insulating layer 22. The source electrode 25a and the drain electrode 25b are electrically connected to the active layer 23.

The organic light-emitting display apparatus 200 may further include, for example, a barrier layer 10 interposed between the substrate 1 and the thin film transistor 2′.

The barrier layer 10 may be formed of, for example, at least one of the various inorganic and organic layers. Moisture passing through the organic light-emitting display apparatus 200 may decrease the lifetime of the organic light-emitting diode 3. Thus, the barrier layer 10 prevents unnecessary impurities such as, for example, moisture from passing through the substrate 1 and penetrating into the organic light-emitting diode 3.

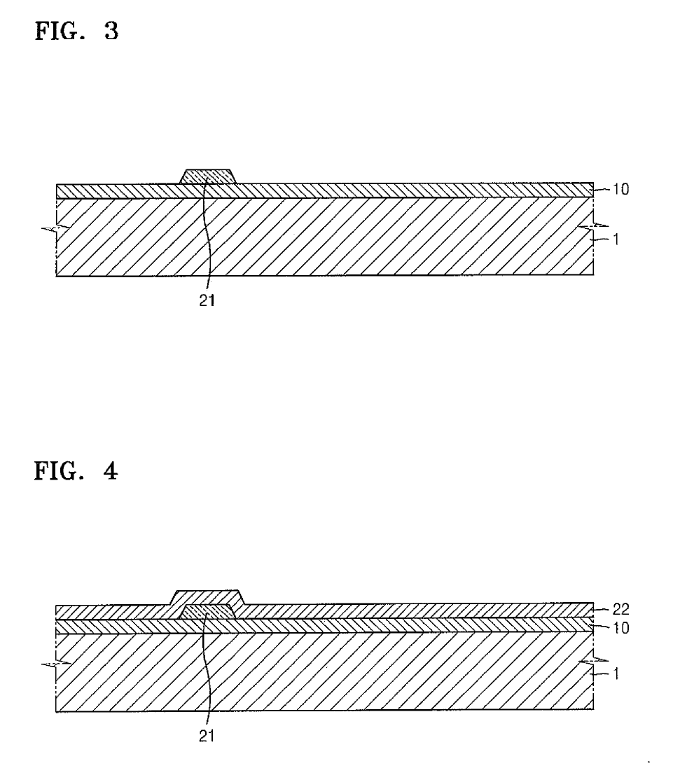

FIGS. 3 through 10 are cross-sectional views illustrating a method of manufacturing the organic light-emitting display apparatus 100 according to an embodiment of the present invention.

Referring to FIG. 3, the substrate 1 is prepared. The substrate 1 may be formed of, for example, transparent glass, quartz, plastic, or the like. Also, in an exemplary embodiment, the substrate 1 may be formed of, for example, ceramic or silicon materials. For example, substrate 1 may be formed of a plastic material such as polyethyelneterepthalate (PET), polyethylenennapthalate (PEN), polycarbonate (PC), polyallylate, polyetherimide (PEI), polyethersulphone (PES), or polyimide. Also, the substrate 1 may be, for example, a metal substrate formed of thin glass or stainless steel. In addition, the substrate 1 may be, for example, a flexible substrate formed of various flexible materials.

The barrier layer 10 may be formed on the substrate 1. The barrier layer 10 may be formed of, for example, at least one of various inorganic and organic layers.

Next, a conductive material such as, for example, a metal or a conductive metal oxide is coated on the substrate 1 and is patterned to form the gate electrode 21.

Referring to FIG. 4, an insulating material is coated on an upper portion of the gate electrode 21 and is patterned to form the gate insulating layer 22.

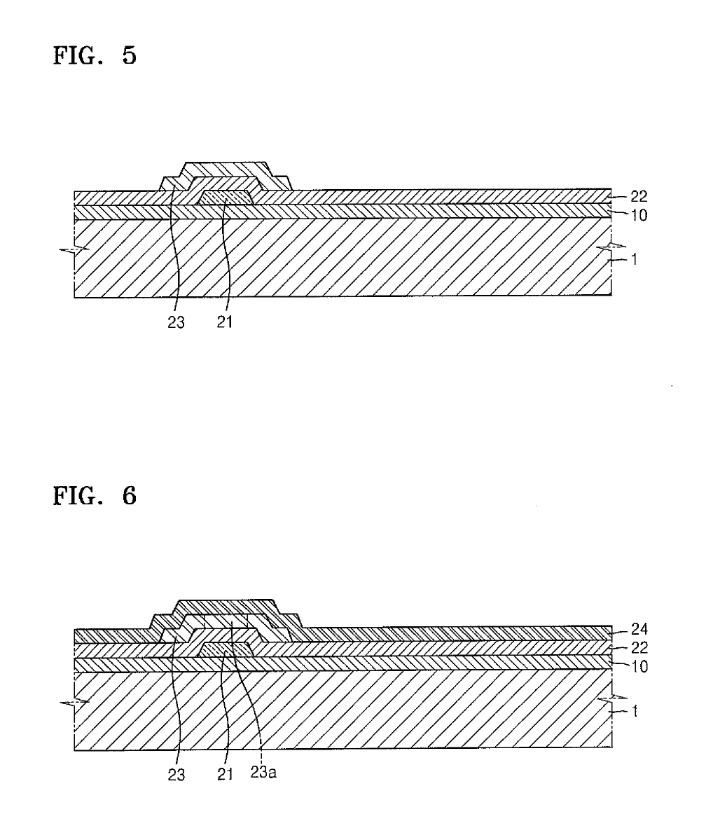

Referring to FIG. 5, a semiconductor material is coated on the gate insulating layer 22 that corresponds to the gate electrode 21 by using, for example, physical vapor deposition (PVD), chemical vapor deposition (CVD), or atomic layer deposition (ALD). The semiconductor material may be, for example, a gallium-indium-zinc-oxide (GIZO) layer including a(In2O3), b(Ga2O3), and c(ZnO) (a, b, and c are real numbers such that a≧0, b≧0, and c≧0), or an HfInZnO layer.

Referring to FIG. 6, the insulating layer 24 is patterned to cover the active layer 23.

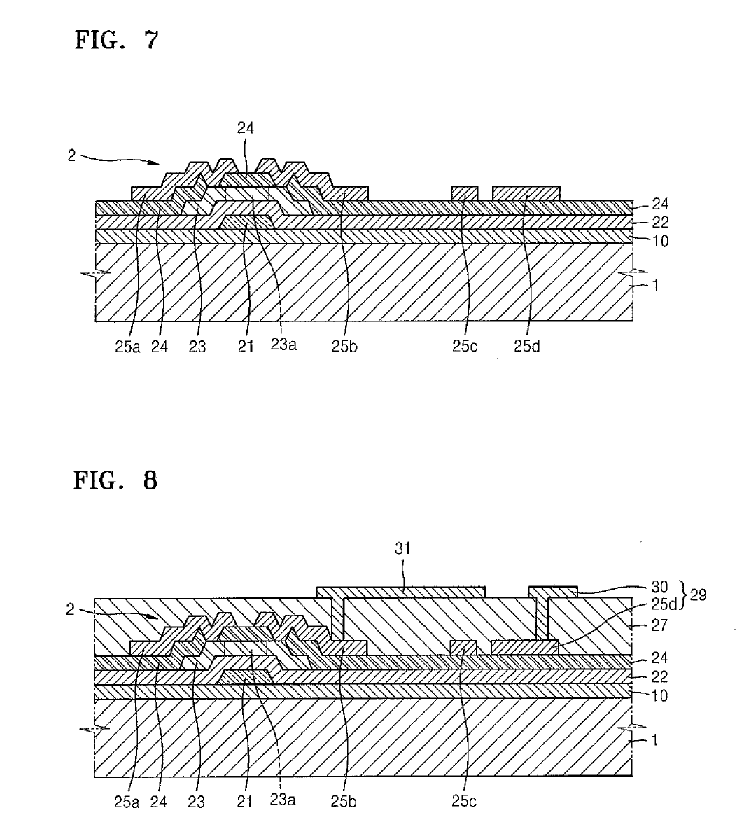

Referring to FIG. 7, holes are formed in the insulating layer 24. Then, a conductive material such as, for example, a metal or a conductive metal oxide is coated on the insulating layer 24, and is patterned to be connected to both sides of the active layer 23. Thus, the source and drain electrodes 25a and 25b are formed.

The drain electrode 25b is formed, for example, to overlap a predetermined portion of the outer region of the organic light-emitting diode 3 (refer to FIG. 10).

In addition, when forming the source and drain electrodes 25a and 25b, the auxiliary pattern 25c is, for example, concurrently formed on the insulating layer 24. The auxiliary pattern 25c may be formed of, for example, the same material as the source and drain electrodes 25a and 25b.

The auxiliary pattern 25c is, for example, spaced apart from the drain electrode 25b, and formed on the insulating layer 24. The auxiliary pattern 25c is formed, for example, in the lower region of the organic light-emitting diode 3 (refer to FIG. 10) to overlap a predetermined portion of the outer region of the organic light-emitting diode 3.

Additionally, the first conductive pattern 25d may be formed on the insulating layer 24. The first conductive pattern 25d may be formed of, for example, the same material as the source and drain electrodes 25a and 25b.

Referring to FIG. 8, the passivation layer 27 is formed on the insulating layer 24 to cover the source and drain electrodes 25a and 25b, the auxiliary pattern 25c, and the first conductive pattern 25d.

Next, the first electrode 31 of the organic light-emitting diode 3 (refer to FIG. 10), which contacts the drain electrode 25b, and the second conductive pattern 30, which contacts the first conductive pattern 25d are formed on the passivation layer 27.

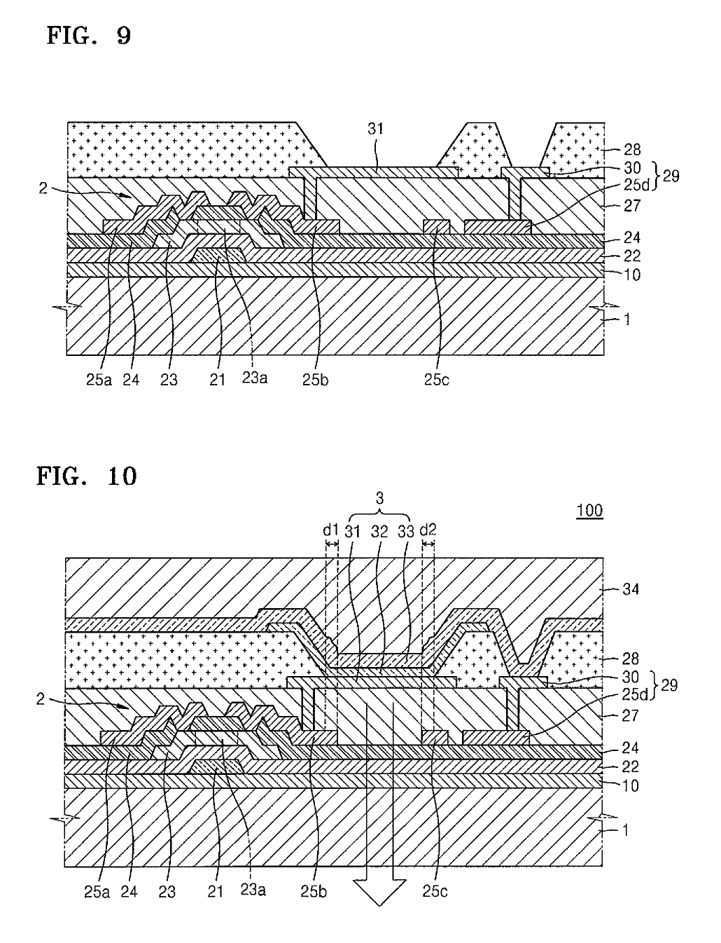

Referring to FIG. 9, the pixel defining layer 28, which exposes a portion of the first electrode 31 and the auxiliary electrode 29, is formed on the passivation layer 27.

Referring to FIG. 10, the organic layer 32 is formed on the upper portion of the first electrode 31 that is exposed by the pixel defining layer 28.

The organic layer 32 may include, for example, all of or selectively include the HIL, the EML, and the EIL. However, the organic layer 32 should at least include the EML .

The organic layer 32 may be formed by using, for example, a printing method. For example, an organic material is injected into the exposed upper portion of the first electrode 31 by using an inkjet printing method, a nozzle printing method, a gravure printing method, a screen printing method, a spray printing method, or an electrostatic printing method, and is then dried to form the organic layer 32.

Next, the second electrode 33 is formed on the upper portions of the organic layer 32 and the auxiliary electrode 29.

Then, the encapsulating layer 34 is formed to encapsulate the second electrode 33. The encapsulating layer 34 may be formed of, for example, a plurality of inorganic layers, or alternately stacked inorganic and organic layers.

According to the present embodiment, to address the difficulty of when the thickness of the organic layer 32 formed in the organic light-emitting diode 3 is non-uniform near the pixel defining layer 28, the drain electrode 25b is formed to overlap a predetermined portion of a lower region of the organic light-emitting diode 3.

Therefore, the drain electrode 25b may prevent the organic light emitting diode 3 from emitting light of different luminance levels due to the non-uniform thickness of the organic layer 32 near the pixel defining layer 28.

Also, as the auxiliary pattern 25c is formed to overlap a predetermined portion of the lower region of the organic light-emitting diode 3, the auxiliary pattern 25c may prevent the organic light emitting diode 3 from emitting light of different luminance levels due to the non-uniform thickness of the organic layer 32 formed on the organic light-emitting diode 3 near the pixel defining layer 28.

In addition, the auxiliary electrode 29 may supply auxiliary power to the second electrode 33, that is, the first and second conductive patterns 25d and 30.

Thus, the occurrence of an IR drop may be prevented, and thus, the luminance and display quality of the organic light-emitting display apparatus 100 may be increased.

Having described exemplary embodiments of the present invention, it is further noted that it is readily apparent to those of ordinary skill in the art that various modifications may be made without departing from the spirit and scope of the invention which is defined by the metes and bounds of the appended claims.

What is claimed is:

1. An organic light-emitting display apparatus comprising:
a thin film transistor comprising a gate electrode, an active layer insulated from the gate electrode, a source electrode and a drain electrode insulated from the gate electrode and contacting the active layer, and an insulating layer disposed between the source and drain electrodes and the active layer; and
an organic light-emitting diode comprising a first electrode, a second electrode and an organic layer disposed between the first electrode and the second electrode, wherein the organic light emitting diode is electrically connected to the thin film transistor,
wherein the drain electrode overlaps with a portion of the organic light-emitting diode.

2. The organic light-emitting display apparatus of claim 1, wherein the organic light-emitting diode is a bottom emission type organic light-emitting diode configured to emit light through a substrate.

3. The organic light-emitting display apparatus of claim 1, further comprising an auxiliary pattern spaced apart from the drain electrode and overlapping with a portion of the organic light-emitting diode.

4. The organic light-emitting display apparatus of claim 3, wherein the auxiliary pattern and the drain electrode, which overlaps the organic light-emitting diode, are disposed on a same plane as each other.

5. The organic light-emitting display apparatus of claim 3, wherein an overlapping distance of the drain electrode and the organic light-emitting diode is substantially equal to an overlapping distance of the auxiliary pattern and the organic light-emitting diode.

6. The organic light-emitting display apparatus of claim 1, wherein the organic layer is formed by using a printed method.

7. The organic light-emitting display apparatus of claim 6, wherein the printing method is one selected from the group consisting of an inkjet printing method, a nozzle printing method, a gravure printing method, a screen printing method, a spray printing method and an electrostatic printing method.

8. The organic light-emitting apparatus of claim 1, further comprising an auxiliary electrode comprising:
a first conductive pattern disposed on the insulating layer; and
a second conductive pattern disposed on the first conductive pattern and contacting the second electrode.

9. The organic light-emitting apparatus of claim 8, wherein the first conductive pattern and the drain electrode, which overlaps the organic light-emitting diode, are disposed on a same plane as each other.

10. The organic light emitting apparatus of claim 1, further comprising an encapsulating layer encapsulating the organic light-emitting diode.

11. A method of manufacturing an organic light-emitting apparatus, the method comprising:
forming a gate electrode on a substrate;
forming a gate insulating layer covering the gate electrode;
forming an active layer on the gate insulating layer;
forming an insulating layer covering at least a channel region of the active layer;
forming a source electrode and a drain electrode contacting the active layer on the insulating layer; and
forming an organic light-emitting diode electrically connected to either one of the source and drain electrodes, wherein the organic light-emitting diode includes a first electrode, a second electrode and an organic layer disposed between the first electrode and the second electrode,
wherein the forming of the drain electrode comprises overlapping the drain electrode with a portion of the organic light-emitting diode.

12. The method of claim 11, wherein in the forming of the organic light-emitting diode, the organic light-emitting diode is formed as a bottom emission type light-emitting diode configured to emit light through the substrate.

13. The method of claim 11, wherein the forming of the source and drain electrodes further comprises forming an auxiliary pattern spaced apart from the drain electrode and overlapping with a portion of the organic light-emitting diode.

14. The method of claim 13, wherein in the forming of the auxiliary pattern, the auxiliary pattern and the drain electrode are formed on a same plane as each other.

15. The method of claim 13, wherein in the forming of the auxiliary pattern, the auxiliary pattern is formed of a same material as the source and drain electrodes.

16. The method of claim 11, wherein in the forming of the organic light-emitting diode, the organic layer is formed by using a printing method.

17. The method of claim 16, wherein the printing method is one selected from the group consisting of an inkjet printing method, a nozzle printing method, a gravure printing method, a screen printing method, a spray printing method, and an electrostatic printing method.

18. The method of claim 11, wherein the forming of the source and drain electrodes further comprises:
forming a first conductive pattern on the insulating layer; and
forming a second conductive pattern on the first conductive pattern to contact the second electrode.

19. The method of claim 11, further comprising, before the forming of the gate electrode, forming a barrier layer on the substrate.

20. The method of claim 11, further comprising, after the forming of the organic light-emitting diode, forming an encapsulating layer encapsulating the organic light-emitting diode.
